(19) United States
(12) Patent Application Publication
(10) Pub. No.: US 2009/0016214 A1
(43) Pub. Date: Jan. 15, 2009

(54) Method and system for network recovery from multiple link failures

(75) Inventors: Paul Alluisi, Raleigh, NC (US); Matt Sannipoli, Wake Forest, NC (US); Mayasandra Srikrishna, Raleigh, NC (US)

Correspondence Address: ARENT FOX LLP, 1050 CONNECTICUT AVENUE, N.W., SUITE 400, WASHINGTON, DC, 20036, US

(73) Assignee: Allied Telesis Holdings K.K.

(21) Appl. No.: 11/826,203

(22) Filed: Jul. 12, 2007

(51) Int. Cl. G01R 31/08

(52) U.S. Cl. 370/228

(57) ABSTRACT

A method and system for fast and reliable network recovery from multiple link failures that detect the presence of an isolated node or segment in the network and determine whether one of the failed links, flanked by two blocked ports, is restored. Upon determining that at least one remaining link on the network remains in a failed state, a message is transmitted to all network links to indicate that one failed link is restored, and to unblock the ports flanking the restored link. The method and system of the present invention then flush the forwarding tables of all nodes, and network traffic resumes on the new network topology.

### BACKGROUND OF THE INVENTION

1. Field of the Invention

The present invention relates generally to a method and system for network recovery from multiple link failure conditions. In particular, the present invention is directed towards a method and system for providing fast network recovery, while avoiding loops and maintaining uninterrupted network operations in response to multiple link failures within the network.

2. Description of Related Art

The focus of modern network communications is directed to delivering services, such as broadcast video, Plain Old telephone Service (POTS), Voice over Internet Protocol (VoIP), video on demand, and Internet access, and deploying these services over an Ethernet-based network. In recent years, the types services provided, their quality and sophisticated implementation, have all been improving at a steady pace. In terms of providing uninterrupted network operations and fast responses to network link failures, however, today's Ethernet-based network communications are falling behind. Some additional shortcomings of existing Ethernet-based networks include unreliable self-recovery from multiple link failures, and inability to make the failures and the recovery unnoticeable to the subscriber.

Existing network protocols, such as the Spanning Tree Protocol (“STP”), initially specified in ANSI/IEEE Standard 802.1D, 1998 Edition, and the Multiservice Access Platform (“MAP”) enhancements provided by the Rapid Spanning Tree Protocol (“RSTP”), defined in IEEE Standard 802.1w-2001, are effective for loop-prevention and assuring availability of backup paths, and are incorporated by reference herein in their entirety. Although these protocols provide the possibility of disabling redundant paths in a network to avoid loops, and automatically re-enabling them when necessary to maintain connectivity in the event of a network failure, both protocols are slow in responding to and recovering from network failures. The response time of STP/RSTP to network failures is on the order of 30 seconds or more. This slow response to failures is due, in part, to the basics of STP/RSTP operations, which are tied to calculating the locations of link breakage points on the basis of user-provided values that are compared to determine the best (or lowest cost) paths for data traffic.

Another existing network algorithm and protocol, Ethernet Protection Switched Rings (“EPSR”), developed by Allied Telesis Holdings Kabushiki Kaisha of North Carolina on the basis of Internet standards-related specification Request for Comments (“RFC”) 3619, is a ring protocol that uses a fault detection scheme to alert the network that a failure has occurred, and indicates to the network to take action, rather than perform path/cost calculations. The EPSR, however, although much faster to recover from a single link failure than STP/RSTP, suffers from the drawback that recovery from multiple link failures is not possible, and traffic on the network cannot be restored (interchangeably referred to herein as “converged”), until recovery of all failed links. Moreover, self-recovery from multiple link failures is unreliable, and even if ultimately accomplished, is cumbersome, slow, and does not reliably prevent loops in the network.

There is a general need, therefore, for methods and systems that provide network recovery from multiple link failure conditions. There is a further need for methods and systems that provide network recovery from multiple link failure conditions that are fast, provide reliable self-recovery from failures, and make the failures and the recovery unnoticeable to the subscriber, while preventing the forming of network loops.

### SUMMARY OF THE INVENTION

The present invention meets the above-identified needs, as well as others, by providing methods and systems for network recovery from failure conditions that are fast, reliable, and make the failures and the recovery unnoticeable or barely noticeable to the subscriber.

Further, the method and system of the present invention provide the above advantages, while preserving the network capacity to avoid loops.

In an exemplary embodiment, the present invention provides a system and method for recovery from network failures by designating a master and transit nodes in a ring network configuration, and when a failed link occurs, blocking the associated ports of the nodes adjacent to the failed link. In this embodiment, the network proceeds to determine whether multiple link failures are detected (e.g., by detecting an isolated node), and whether at least one failed link is recovered, while another remains in a failed state. Upon determining that another port on the network is blocked, the present invention transmits a message to each network node indicating that the failed link is restored, unblocks the first restored link blocked port and the second restored link blocked port associated with each of the restored links, and flushes the bridge tables associated with each node. The nodes then proceed to identify and adopt the new topology (interchangeably referred to herein as “learning” the new topology), and network traffic is resumed.

Additional advantages and novel features of the invention will be set forth in part in the description that follows, and in part will become more apparent to those skilled in the art upon examination of the following or upon learning by practice of the invention.

### BRIEF DESCRIPTION OF THE FIGURES

In the drawings:

FIG. 1 illustrates the operation of an exemplary EPSR network in a normal (non-failed) state, as occurs in accordance with embodiments of the present invention.

FIG. 2 illustrates the operation of an exemplary EPSR network upon discovery of a single failed link, as occurs in accordance with embodiments of the present invention.

FIG. 3 shows the operation of an exemplary EPSR network in recovery from a single failed link, as occurs in accordance with embodiments of the present invention.

FIG. 4 illustrates a multiple link failure in an exemplary EPSR network, as occurs in accordance with embodiments of the present invention.

FIG. 5 shows recovery of a single link failure in an exemplary EPSR network with multiple failed links, in accordance with an embodiment of the present invention.

FIG. 6 shows recovery of a last link in an exemplary EPSR network with multiple failed links, in accordance with an embodiment of the present invention.

FIG. 7 shows recovery of a last link in an exemplary EPSR network with multiple failed links, in accordance with an embodiment of the present invention.

FIG. 8 presents a flow chart of the sequence of actions performed for network recovery from multiple link failures, in accordance with an embodiment of the present invention.

FIG. 9 presents a flow chart of a method for network recovery from multiple link failures in accordance with an embodiment of the present invention.

FIG. 10 shows various features of an example networked computer system, including various hardware components and other features for use in conjunction with an embodiment of the present invention.

### DETAILED DESCRIPTION

For a more complete understanding of the present invention, the needs satisfied thereby, and the objects, features, and advantages thereof, an illustration will first be provided of an exemplary EPSR Ethernet-based network recovery from a single link failure, and then an illustration will be provided of an exemplary EPSR network recovery from multiple link failures.

### Exemplary Network Recovery From Single Link Failure

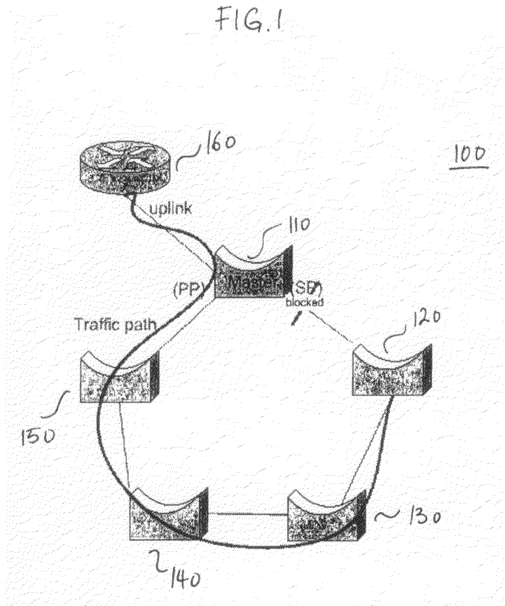

An exemplary EPSR Ethernet-based network recovery from a single link failure will now be described in more detail with reference to FIGS. 1-4, like numerals being used for like corresponding parts in the various drawings.

FIG. 1 illustrates the operation of an exemplary EPSR network in a normal (non-failed) state. An existing EPSR network 100, shown in FIG. 1, includes a plurality of network elements (interchangeably referred to herein as “nodes”) 110-160, e.g., switches, routers, and servers, wherein each node 110-160 includes a plurality of ports. A single EPSR ring 100, hereinafter interchangeably referred to herein as an EPSR “domain,” has a single designated “master node” 110. The EPSR domain 100 defines a protection scheme for a collection of data virtual local area networks (“VLANs”), a control VLAN, and the associated switch ports. The VLANs are connected via bridges, and each node within the network has an associated bridge table (interchangeably referred to herein as a “forwarding table”) for the respective VLANs.

The master node 110 is the controlling network element for the EPSR domain 100, and is responsible for status polling, collecting error messages, and controlling the traffic flow on an EPSR domain. All other nodes 120-150 on that ring are classified as “transit nodes.” Transit nodes 120-150 generate failure notices and receive control messages from the master node 110.

Each node on the ring 100 has at least two configurable ports, primary and secondary, connected to the ring. One port of the master node is designated as the “primary port,” while a second port is designated as the “secondary port.” The primary and secondary ports of master node 110 are respectively designated as PP and SP in FIG. 1. The primary port PP of the master node 110 determines the direction of the traffic flow, and is always operational. In normal operation, the master node 110 blocks' the secondary port SP for all non-control Ethernet frames belonging to the given EPSR domain, thereby preventing the formation of a loop in the ring. In normal operation, the secondary port SP of the master node 110 remains active, but blocks all protected VLANs from operating until a ring failure is detected. Existing Ethernet switching and learning mechanisms operate on this ring in accordance with existing standards. This operation is possible because the master node causes the ring to appear as though it contains no loop, from the perspective of the Ethernet standard algorithms used for switching and learning.

If the master node 110 detects a ring fault, it unblocks its secondary port SP and allows Ethernet data frames to pass through that port. A special “control VLAN” is provided that can always pass through all ports in the domain, including the secondary port SP of the master node 110. The control VLAN cannot carry any data traffic; however, it is capable of carrying control messages. Only EPSR control packets are therefore transmitted over the control VLAN. Network 100 uses both a polling mechanism and a fault detection mechanism (interchangeably referred to herein an “alert”), each of which is described in more detail below, to verify the connectivity of the ring and quickly detect faults in the network.

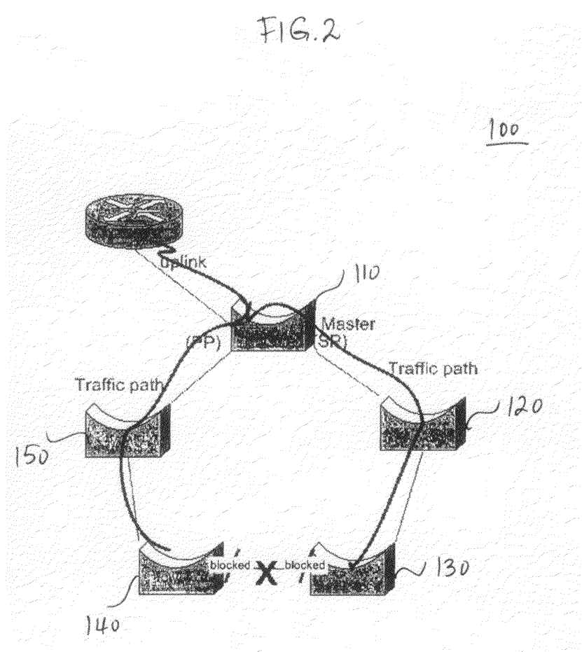

The fault detection mechanism will now be described with reference to FIG. 2. Upon detection by a transit node 140 of a link-down on any of its ports connected to the EPSR domain 100, that transit node immediately transmits a “link down” control frame on the control VLAN to the master node 110. When the master node 110 receives this “link down” control frame, the master node 110 transitions from a “normal” state to a “ring-fault” state and unblocks its secondary port. The master node 110 also flushes its bridge table, and sends a control frame to remaining ring nodes 120-150, instructing them to flush their bridge tables, as well. Immediately after flushing its bridge table, each node learns the new topology, thereby restoring all communications paths.

It is possible that, due to an error, the “link down” alert frame fails to reach master node 110. In this situation, EPSR domain 100 uses a ring polling mechanism as an alternate way to discover and/or locate faults. The ring polling mechanism will now be described in reference to FIG. 2. The master node 110 sends a health-check frame on the control VLAN at a user-configurable fail period interval. If the ring is complete, the health-check frame will be received on the master node's secondary port SP, at which point the master node 110 will reset its fail period timer and continue normal operation. If, however, the master node 110 does not receive the health-check frame before the fail-period timer expires, the master node 110 transitions from the normal state to the “ring-fault” state and unblocks its secondary port SP. As with the fault detection mechanism, the master node also flushes its bridge table and transmits a control frame to remaining network nodes 120-150, instructing these nodes to also flush their bridge tables. Again, as with the fault detection mechanism, after flushing its bridge table, each node learns the new topology, thereby restoring all communications paths.

The master node 110 continues transmitting periodic health-check frames out of its primary port PP, even when operating in a ring-fault state. Once the ring is restored, the next health-check frame will be received on the secondary port SP of the master node 110. When a health check message is received at the secondary port SP of the master node 110, or when a link up message is transmitted by a previously failed transit node 140, the master node 110 restores the original ring topology by blocking its secondary port to protected VLAN traffic, flushing its bridge table, and transmitting a control message to the transit nodes 120-150 to flush their bridge tables, re-learn the topology, and restore the original communication paths.

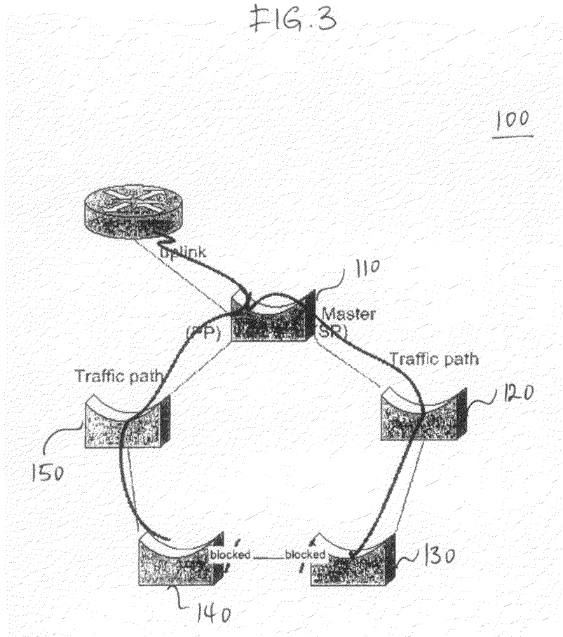

During the period of time between a) detection by the transit nodes 140 and 150 that the link between them is restored, and b) the master node 110 detecting that the ring 100 is restored, the secondary port SP of the master node remains open, thereby creating the possibility of a temporary loop in the ring. To prevent this loop from occurring, as shown in FIG. 3, when the failed link first becomes operational, the affected transit nodes 140 and 150 temporarily block the associated ports until a message is received from the master node 110 that it is safe to unblock the affected ports (i.e., such that no loop can occur). A network loop is thus prevented from occurring when the failed link is first restored and the master node 110 still has its secondary port SP open to protected VLAN traffic.

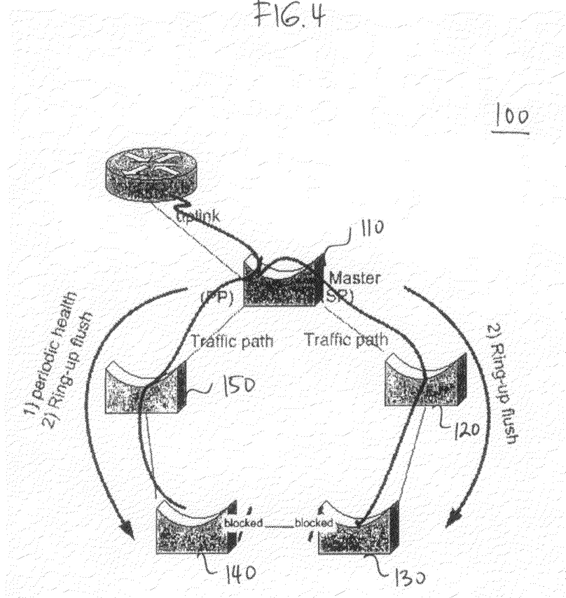

Once the master node 110 has re-blocked its secondary port SP and flushed its forwarding database, the master node 110 transmits a network restored “ring-up flush” control message to the transit nodes 120-150, as shown in FIG. 4. In response, the transit nodes 120-140 flush their bridge tables and unblock the ports associated with the newly restored link, thereby restoring the ring to its original topology, and restoring the original communications paths. Since no calculations are required between nodes, the original ring topology can be quickly restored, (e.g., in 50 milliseconds or less), with no possibility of an occurrence of a network loop.

It is possible to have several EPSR domains simultaneously operating on the same ring. Each EPSR domain has its own unique master node and its own set of protected VLANs, which facilitates spatial reuse of the ring's bandwidth.

### Exemplary Network Recovery From Multiple Link Failures

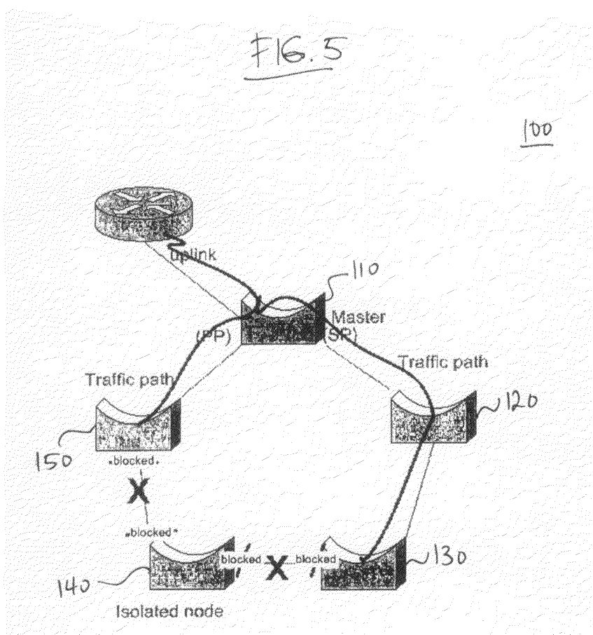

An exemplary EPSR Ethernet-based network recovery from multiple link failures will now be described in more detail with reference to FIGS. 5-8, like numerals being used for like corresponding parts in the various drawings.

FIG. 5 illustrates the situation where two adjacent links in ring 100 fail. The transit nodes 130, 140 and 150, affected by the link failure, block their corresponding ports to prevent a loop from occurring when one or both of the links recover. As in the case with network recovery from single link failure, all other transit nodes 120 have both ring ports in a forwarding state, and the master node 110 has its primary port PP in the forwarding state. In response to the link failure, the master node 110 unblocks its secondary port SP to network traffic. Thus, network traffic will flow through both the primary PP and secondary ports SP of the master node 110. In the situation of multiple link failure, at least one transit node 140 is isolated from the network 100. Two or more nodes will be isolated from the network 100 if they are connected to each other via operating links, but separated from the network via failed links.

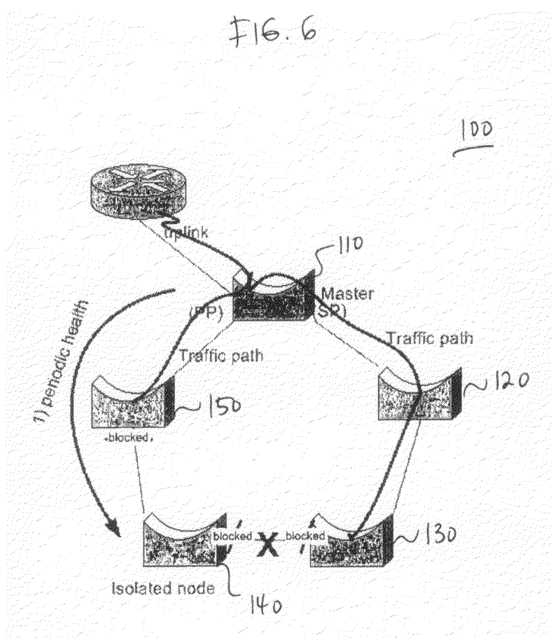

As shown in FIG. 6, upon recovery of one of the failed links, the two affected transit nodes 140 and 150 must determine whether it is safe (e.g., without significant risk of looping) to unblock the ports, on each side of the failed link. When the isolated transit node 140 (or an isolated network segment) has both of its ports blocked, unblocking one of its ports cannot result in a network loop. Thus, it is safe for the isolated transit node 140 to unblock its recovered port, since the link at its second port remains in a failed state, and its second port is blocked. The other affected transit node 150 has one of its ring ports in the forwarding state and, therefore, must keep the recovered port in the blocked state because it does not have enough information to determine whether it is safe to unblock its recovered port.

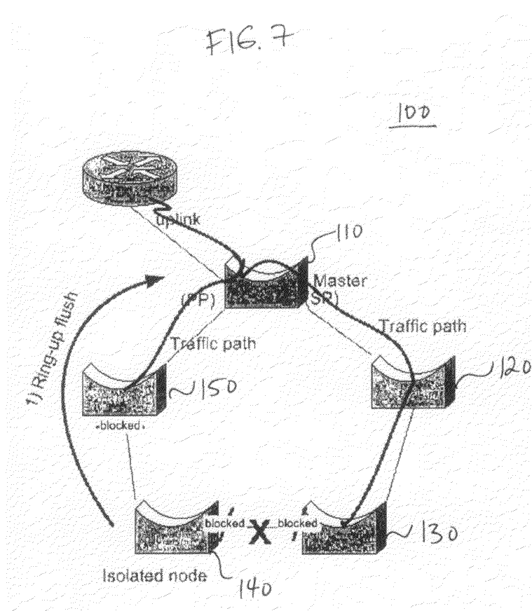

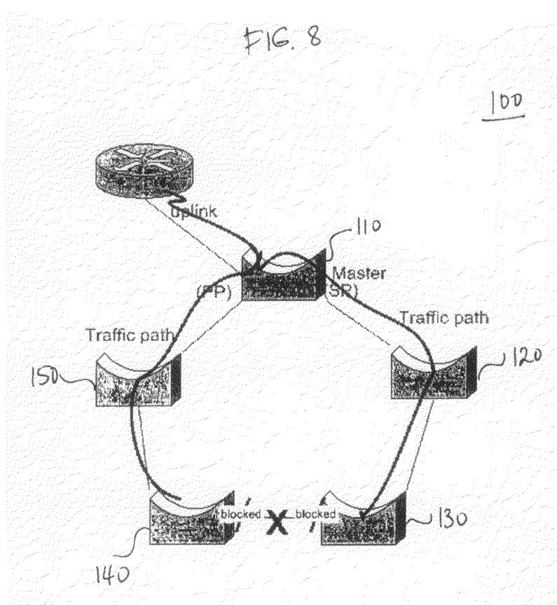

In accordance with one embodiment of the present invention, when a port of the isolated node 140 recovers, the transit node 140 transmits a “ring-up flush” message to the other nodes 150, 110, 120 and 130, as if this message were transmitted by the master node. In this case, as shown in FIG. 7, the isolated transit node 140 receives the “ring-up flush” message to the remaining nodes 150, 110, 120 and 130. When the transit node 150 receives the “ring-up flush” message from heretofore isolated transit node 140, the transit node 150 flushes its forwarding table and unblocks its recovered port, thereby restoring the network traffic flow (and thus node 150) to the ring, as shown in FIG. 8. The present invention thereby provides fast, efficient and effective management of redundant paths and node ports to maintain and/or restore traffic flow upon multiple link network failure and recovery.

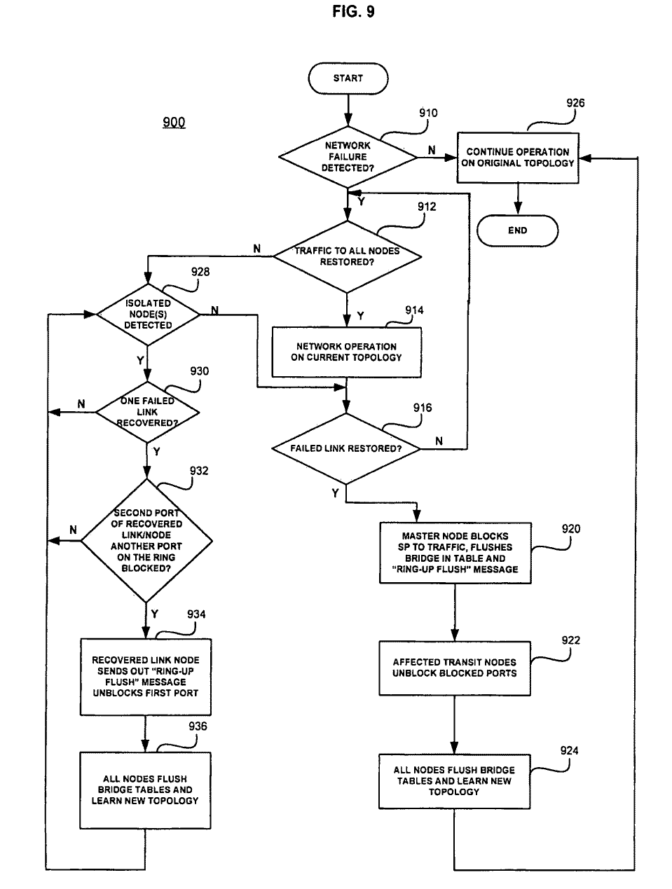

The method for network recovery from multiple link failures, in accordance with one embodiment of the present invention, will now be described with reference to FIG. 9.

As shown in FIG. 9, upon detection of network failure 910, a determination is made whether traffic to all nodes of the network has been restored 912. In one embodiment, the network failure detection 910 may be achieved via a ring polling mechanism or fault detection mechanism, described in detail above. One of ordinary skill in the art will recognize, however, that network failure detection 910 may be achieved by any methods or devices that may accomplish such detection.

If the traffic to all nodes has been restored 912, despite the existence of a network failure 910, the network continues to operate with the new topology 914 that all nodes learned before the traffic could be restored. The determination of whether the failed link has been recovered 916 may be achieved by the master node receiving the periodically transmitted health check message on its secondary port, thus recognizing that the network has been restored. One of ordinary skill in the art will recognize, however, that the determination of whether a failed link has been recovered may be accomplished by other available methods or devices. Upon recognizing that the network has been restored, the master node blocks its secondary port to data traffic, flushes its forwarding table, and transmits a “ring-up flush” message to the remaining nodes in the network 920. The affected transit nodes will at this point unblock their failure-affected ports 922. All nodes then flush their forwarding tables, learn the new network topology 924, and the network continues operation 926.

If the failed link has not been recovered 916, a determination is again made whether the traffic to all nodes has been restored 912 and, if so, operation continues on the new topology, until the failed link is recovered 916.

If the traffic to all nodes has not been restored 912, a determination is made whether one or more isolated nodes have been detected 928. If no isolated nodes are detected 928, a determination is made whether the failed link has been recovered 916, and operations continue as described above, depending on whether the failed link has been recovered or not 916.

If, however, one or more isolated nodes/segments are detected 928, at least two failed links now exist, and a determination is made whether one of the failed links has been recovered 930. If one of the failed links has been recovered 930, a determination is made whether the second port of the recovered link node is blocked 932 (or a port of another node on the ring, except the two recovered link ones). If the second port of the recovered link node is blocked 932 (or if a port of another node on the ring, other than the two recovered link nodes is blocked), then it is “safe” to unblock it, as the possibility of a loop occurring is none or insignificant, due to the fact the at least one more failed link exists in the network, as determined in 928.

Upon determining that it is safe to unblock the second port of the recovered link node 932, the recovered link node transmits a “ring-up flush” message, as if the recovered link node were the master node, and unblocks its first port 934. At this point, all nodes flush their forwarding tables and learn the new network topology.

If no more isolated nodes are detected 928, a determination is made whether the failed link has been recovered 916, and operations continue as described above, depending on whether the failed link has been recovered or not 916.

If no failed links are recovered 930, traffic does not flow on the network until such time that a failed link is recovered. Similarly, if the second port of a recovered link (or another port on a node other than the recovered link nodes) is not blocked 932, the network will not carry traffic, and a determination will again be made whether one or more isolated nodes have been detected.

As described above, the system and method of the present invention support fault-tolerant, loop-free, and easily maintained networks by providing redundant data paths among network components, in which all but one of the data paths between any two components are blocked to network traffic, thereby preventing a network loop, and unblocking an appropriate redundant data path to maintain connectivity when a network component fails, or when a component is added to or removed from the network.

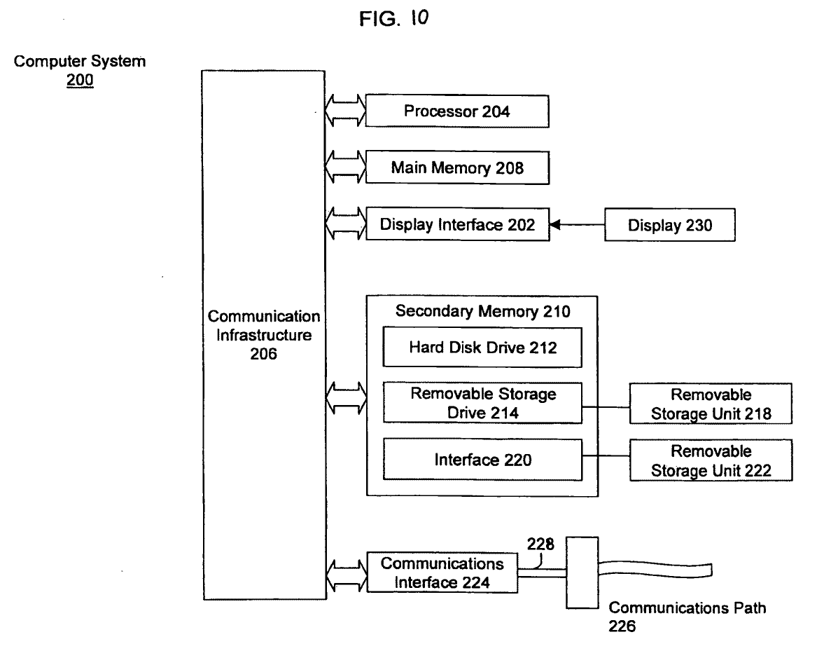

The present invention may be implemented using hardware, software or a combination thereof and may be implemented in one or more computer systems or other processing systems. In one embodiment, the invention is directed toward one or more computer systems capable of carrying out the functionality described herein. An example of such a computer system 200 is shown in FIG. 10.

Computer system 200 includes one or more processors, such as processor 204. The processor 204 is connected to a communication infrastructure 206 (e.g., a communications bus, cross-over bar, or network). Various software embodiments are described in terms of this exemplary computer system. After reading this description, it will become apparent to a person skilled in the relevant art(s) how to implement the invention using other computer systems and/or architectures.

Computer system 200 can include a display interface 202 that forwards graphics, text, and other data from the communication infrastructure 206 (or from a frame buffer not shown) for display on the display unit 230. Computer system 200 also includes a main memory 208, preferably random access memory (RAM), and may also include a secondary memory 210. The secondary memory 210 may include, for example, a hard disk drive 212 and/or a removable storage drive 214, representing a floppy disk drive, a magnetic tape drive, an optical disk drive, etc. The removable storage drive 214 reads from and/or writes to a removable storage unit 218 in a well-known manner. Removable storage unit 218, represents a floppy disk, magnetic tape, optical disk, etc., which is read by and written to removable storage drive 214. As will be appreciated, the removable storage unit 218 includes a computer usable storage medium having stored therein computer software and/or data.

In alternative embodiments, secondary memory 210 may include other similar devices for allowing computer programs or other instructions to be loaded into computer system 200. Such devices may include, for example, a removable storage unit 222 and an interface 220. Examples of such may include a program cartridge and cartridge interface (such as that found in video game devices), a removable memory chip (such as an erasable programmable read only memory (EPROM), or programmable read only memory (PROM)) and associated socket, and other removable storage units 222 and interfaces 220, which allow software and data to be transferred from the removable storage unit 222 to computer system 200.

Computer system 200 may also include a communications interface 224. Communications interface 224 allows software and data to be transferred between computer system 200 and external devices. Examples of communications interface 224 may include a modem, a network interface (such as an Ethernet card), a communications port, a Personal Computer Memory Card International Association (PCMCIA) slot and card, etc. Software and data transferred via communications interface 224 are in the form of signals 228, which may be electronic, electromagnetic, optical or other signals capable of being received by communications interface 224. These signals 228 are provided to communications interface 224 via a communications path (e.g., channel) 226. This path 226 carries signals 228 and may be implemented using wire or cable, fiber optics, a telephone line, a cellular link, a radio frequency (RF) link and/or other communications channels. In this document, the terms “computer program medium” and “computer usable medium” are used to refer generally to media such as a removable storage drive 214, a hard disk installed in hard disk drive 212, and signals 228. These computer program products provide software to the computer system 200. The invention is directed to such computer program products.

Computer programs (also referred to as computer control logic) are stored in main memory 208 and/or secondary memory 210. Computer programs may also be received via communications interface 224. Such computer programs, when executed, enable the computer system 200 to perform the features of the present invention, as discussed herein. In particular, the computer programs, when executed, enable the processor 204 to perform the features of the present invention. Accordingly, such computer programs represent controllers of the computer system 200.

In an embodiment where the invention is implemented using software, the software may be stored in a computer program product and loaded into computer system 200 using removable storage drive 214, hard drive 212, or communications interface 224. The control logic (software), when executed by the processor 204, causes the processor 204 to perform the functions of the invention as described herein. In another embodiment, the invention is implemented primarily in hardware using, for example, hardware components, such as application specific integrated circuits (ASICs). Implementation of the hardware state machine so as to perform the functions described herein will be apparent to persons skilled in the relevant art(s).

While the present invention has been described in connection with preferred embodiments, it will be understood by those skilled in the art that variations and modifications of the preferred embodiments described above may be made without departing from the scope of the invention. Other embodiments will be apparent to those skilled in the art from a consideration of the specification or from a practice of the invention disclosed herein. It is intended that the specification and the described examples are considered exemplary only, with the true scope of the invention indicated by the following claims.

What is claimed is:

1. A method of network recovery from link failure, the network comprising a master node, a plurality of transit nodes and a plurality of links, each node having at least two ports, a link from the plurality of links coupling a first port of each node to a second port of another node, the method comprising:
identifying at least one isolated network segment, an isolated network segment comprising at least one node having a first failed link and a second failed link;
blocking the ports associated with the failed links, each of the failed links having a first blocked port and a second blocked port;
determining that at least one of the first and second failed links is restored, each of the restored links having an associated first restored link blocked port and a second restored link blocked port;
transmitting a message to each network node, the message indicating that the failed link is restored;
unblocking the first restored link blocked port and the second restored link blocked port associated with each of the restored links; and
flushing bridge tables associated with each node.

2. The method of claim 1, further comprising:
creating updated bridge tables associated with each node.

3. The method of claim 2, further comprising:
restoring traffic flow on the network.

4. A method of network recovery from link failure, the network comprising a master node, a plurality of transit nodes and a plurality of links, each node having at least two ports and an associated bridge table, a link from the plurality of links coupling a first port of each node to a second port of another node, the method comprising:
detecting a failed link in the network;
blocking the ports associated with the failed link; and
upon determining that network traffic has been restored to all nodes,
blocking a secondary port of the master node;
flushing the bridge table of the master node; and
transmitting a message to the plurality of transit nodes to flush each associated bridge table.

5. The method of claim 4, further comprising:
creating new bridge table for each node.

6. The method of claim 5, further comprising:
restoring traffic flow on an original topology.

7. The method of claim 4, further comprising:
determining whether the failed link is restored; and
upon determining that the failed link is not restored, continuing network operation on an existing topology.

8. A system for network recovery from link failure, the network comprising a master node, a plurality of transit nodes and a plurality of links, each node having at least two ports, a link from the plurality of links coupling a first port of each node to a second port of another node, the system comprising:
means for locating at least one isolated network segment, an isolated network segment comprising at least one node having a first failed link and a second failed link;
means for blocking the ports associated with the failed links, each of the failed links having a first blocked port and a second blocked port;
means for determining that at least one of the first and second failed links is restored, each of the restored links having an associated first restored link blocked port and a second restored link blocked port;
means for sending a message to each network indicating that the failed link is restored;
means for unblocking the first restored link blocked port and the second restored link blocked port associated with each of the restored links; and
means for flushing bridge tables associated with each node.

9. The system of claim 8, further comprising:
means for creating updated bridge tables associated with each node.

10. The system of claim 9, further comprising:
means for restoring traffic flow on the network.

11. A system of network recovery from link failure, the network comprising a master node, a plurality of transit nodes and a plurality of links, each node having at least two ports and an associated bridge table, a link from the plurality of links coupling a first port of each node to a second port of another node, the system comprising:
means for detecting a failed link in the network;
means for blocking the ports associated with the failed link;
means for determining that network traffic has been restored to all nodes,
means for blocking a secondary port of the master node;
means for flushing the bridge table of the master node; and
means for sending a message to the plurality of transit nodes to flush each associated bridge table.

12. The system of claim 11, further comprising:
means for creating new bridge table for each node.

13. The system of claim 12, further comprising:
means for restoring traffic flow on an original topology.

14. The system of claim 11, further comprising:
means for determining whether the failed link is restored; and
upon determining that the failed link is not restored, continuing network operation on an existing topology.

15. A computer program product comprising a computer usable medium having control logic stored therein for causing a computer to facilitate network recovery from link failure, the network comprising a master node, a plurality of transit nodes and a plurality of links, each node having at least two ports, a link from the plurality of links coupling a first port of each node to a second port of another node, the control logic comprising:
first computer readable program code means for locating at least one isolated network segment, an isolated network segment comprising at least one node having a first failed link and a second failed link;
second computer readable program code means for blocking the ports associated with the failed links, each of the failed links having a first blocked port and a second blocked port;
third computer readable program code means for determining that at least one of the first and second failed links is restored, each of the restored links having an associated first restored link blocked port and a second restored link blocked port;
fourth computer readable program code means for sending a message to each network node, the message indicating that the failed link is restored;
fifth computer readable program code means for unblocking the first restored link blocked port and the second restored link blocked port associated with each of the restored links; and
sixth computer readable program code means for flushing bridge tables associated with each node.

16. The computer program product of claim 15, further comprising:
seventh computer readable program code means for creating updated bridge tables associated with each node.

17. The computer program product of claim 16, further comprising:
eighth computer readable program code means for restoring traffic flow on the network.

18. A computer program product comprising a computer usable medium having control logic stored therein for causing a computer to facilitate network recovery from link failure, the network comprising a master node, a plurality of transit nodes and a plurality of links, each node having at least two ports and an associated bridge table, a link from the plurality of links coupling a first port of each node to a second port of another node, the control logic comprising:
first computer readable program code means for detecting a failed link in the network;
second computer readable program code means for blocking the ports associated with the failed link;
third computer readable program code means for determining that network traffic has been restored to all nodes,
fourth computer readable program code means for blocking a secondary port of the master node;
fifth computer readable program code means for flushing the bridge table of the master node; and
sixth computer readable program code means for sending a message to the plurality of transit nodes to flush each associated bridge table.

19. The computer program product of claim 18, further comprising:
seventh computer readable program code means for creating new bridge table for each node.

20. The computer program product of claim 19, further comprising:
eighth computer readable program code means for restoring traffic flow on an original topology.
